(19) United States
(12) Patent Application Publication
(10) Pub. No.: US 2024/0380389 A1
(43) Pub. Date: Nov. 14, 2024

(54) ADAPTIVE ROBUST ESTIMATION METHOD AND SYSTEM FOR PARAMETERS OF UNMANNED SURFACE VESSEL

(71) Applicant: SOUTHEAST UNIVERSITY, Nanjing (CN)

(72) Inventors: Guanghui WEN, Nanjing (CN); Han SHEN, Nanjing (CN); Jun ZHOU, Nanjing (CN); Linan WANG, Nanjing (CN); Mengfei NIU, Nanjing (CN)

(21) Appl. No.: 18/249,500

(22) PCT Filed: Jun. 21, 2022
(86) PCT No.: PCT/CN2022/100107

§ 371 Date: Apr. 18, 2023

(30) Foreign Application Priority Data
Jun. 7, 2022 (CN) 202210633604.4

(51) Int. Cl. H03H 21/00

(52) U.S. Cl. CPC H03H 21/003

(57) ABSTRACT

An adaptive robust estimation method and system for parameters of an unmanned surface vessel belongs to the field of automatic control. First, an augmented state estimation problem considering an external disturbance for the unmanned surface vessel is constructed; augmented state vectors include a state vector of the unmanned surface vessel, a parameter vector, and an unknown input vector; and then, depending on a real-time input vector and a measurement vector of a system, a designed adaptive robust unscented Kalman filtering method is employed to obtain model parameters of the unmanned surface vessel.

### TECHNICAL FIELD

The present invention relates to an adaptive robust estimation method and system for parameters of an unmanned surface vessel and belongs to the field of automatic control. Robust Kalman filtering is designed by means of a robust optimal criterion to weaken influences of outlier noises on identification results, and statistical characteristics of process noises are estimated by means of an adaptive method, thereby improving the estimation accuracy and robustness of unknown parameters of the unmanned surface vessel.

### BACKGROUND

A process during which specific numerical values of model parameters of a control system are estimated based on input vectors and measurement vectors of the control system is referred to as parameter estimation. Adaptive estimation is to adaptively adjust algorithm parameters during an estimation process. However, in Kalman filtering, the estimation of statistical characteristics of noises, especially a covariance matrix of the noises, is a major problem to be taken into account during the design of an adaptive law. Robust estimation is a type of estimation algorithms with good robustness. Parameter estimation is an important technology in the field of automatic control. In engineering practice, the design of a model-based controller and the selection of its parameters can be performed on the premise that an accurate system model and model parameters of a controlled object are known. The provision of accurate model parameters will help to ensure the controller to play a good control effect. With the development of unmanned systems, the controlled object has presented higher complexity in terms of kinematic and dynamical models at present. Therefore, higher requirements have been put forward for the accuracy of parameter estimation.

With the development of the unmanned systems, unmanned surface vessels have drawn great attention in both military and civilian areas at present, and are often used in scenes such as environment monitoring, maritime search and rescue, and resource exploration. In recent years, a great deal of researches also has been carried out on parameter estimation problems of the unmanned surface vessels. For example, Parameter Estimation for Unmanned Surface Vessels Based on Quadratic Programming [Wang X, Zhao J, Geng T. Nonlinear modeling and identification of vessel based on constrained quadratic programming method [C]. 39th Chinese Control Conference (CCC). Shenyang, China; IEEE. 2020: 1028-33.], this method considers constraint conditions possibly present in a model parameter estimation problem of the unmanned surface vessels to obtain better parameter estimation results, but an optimization problem is only established for measurement noises, without considering the influences of the process noises. For example, Parameter Estimation for Unmanned Surface Vessels Based on Extended Kalman Filtering [Perera L P, Oliveira P, Guedes Soares C. System identification of nonlinear vessel steering [J]. Journal of Offshore Mechanics and Arctic Engineering, 2015, 137(3).], this method considers the process noises and the measurement noises, and the establishment of the optimization problem is more complete. However, it is difficult for the extended Kalman filtering to have good accuracy when coping with unmanned surface vessel models with strongly nonlinear dynamics. In addition, this method also does not consider the influences of outlier noises and unknown noise characteristics.

### SUMMARY

Invention objective: To overcome the deficiencies in the prior art, the present invention provides an adaptive robust estimation method and system for parameters of an unmanned surface vessel, which are used for improving the robustness of estimation of model parameters of the unmanned surface vessel and implementing high-accuracy estimation of a high-dimensional process noise covariance matrix.

Technical solution: To achieve the above invention objective, an adaptive robust estimation method for parameters of an unmanned surface vessel provided by the present invention includes the following steps:
step 1: constructing an augmented state estimation problem considering an external disturbance for the unmanned surface vessel; augmented state vectors including a state vector of the unmanned surface vessel, a parameter vector of an unmanned surface vessel model, and an unknown input vector representing a modeling error of an unmanned surface vessel system and the external disturbance;
step 2: depending on a real-time input vector and a measurement vector of the unmanned surface vessel system, employing an adaptive robust unscented Kalman filtering method having process noise covariance matrix constraints and based on the combination of a maximum cross entropy criterion and a minimum mean square error criterion to obtain model parameters of the unmanned surface vessel; the input vector including a control signal from a shipborne controller, and the measurement vector including data obtained by GPS and IMU measurement;
a method for estimating the process noise covariance matrix including: firstly, employing an innovation-based adaptive method to estimate a noise covariance matrix [symbol] ₖ⁰; then, introducing covariance matrix constraints according to a known structure and dividing a process noise covariance matrix [symbol] ₖ to be estimated into a diagonal block without structure constraints and a diagonal block with structure constraints; and finally, employing KL divergence to construct and solve the following optimization problem:

$${\hat{Q}}_{k}^{1 , {j}_{1}} , {λ}_{k}^{{j}_{2}} = {min}_{{\hat{Q}}_{k}^{1 , {j}_{1}} , {λ}_{k}^{{j}_{2}}} {\int }_{- ∞}^{+ ∞} p ( x \vert {\hat{Q}}_{k}^{0} ) log \frac{p ( x \vert {\hat{Q}}_{k}^{0} )}{p ( x \vert {\hat{Q}}_{k} )} dx ;$$

where k represents the moment; [symbol] ₖ^{1,j}^{₁} represents the diagonal block without structure constraints; λₖ^{j}^{₂} represents a coefficient of the diagonal block [symbol] ₖ^{2,j}^{₂} with structure constraints; [symbol] ₖ^{2,j}^{₂}=λₖ^{j}^{₂} [symbol] ₖ^{c,j}^{₂}, [symbol] ₖ^{c,j}^{₂} is a known structure; j₁=1, . . . , n₁, j₂=1, . . . , n₂ n₁ and n₂ represent the number of the diagonal block without structure constraints and the number of the diagonal block with structure constraints, respectively; p(x| [symbol] ₖ⁰) and p(x| [symbol] ₖ) represent probability density functions of a random variable X with the covariance matrix being [symbol] ₖ⁰ and [symbol] ₖ respectively and obeying zero mean Gaussian distribution.

Preferably, the noise covariance matrix estimated by the innovation-based adaptive method is expressed as:

$${\hat{Q}}_{k}^{0} = \frac{1}{N} {\sum }_{i = {k}_{0}}^{k} ( {\hat{x}}_{i \vert i} - {\hat{x}}_{i \vert i - 1} ) {( {\hat{x}}_{i \vert i} - {\hat{x}}_{i \vert i - 1} )}^{T} , {k}_{0} = k - N + 1 , k \geq N$$

where k₀ represents an initial moment of a sample used for calculating the covariance matrix; N represents the quantity of the sample used; and \hat{x}_{i|i-1} and \hat{x}_{i|i} are a predicted value and an estimated value of the augmented state vector at an i th moment, respectively.

Preferably, the process noise covariance matrix to be estimated is expressed as:

$${\hat{Q}}_{k} = diag [ {\hat{Q}}_{k}^{1 , 1} , ... , {\hat{Q}}_{k}^{1 , {n}_{1}} , {\hat{Q}}_{k}^{2 , 1} , ... , {\hat{Q}}_{k}^{2 , {n}_{2}} ] ;$$

in a case that [symbol] ₖ^{c,j}^{₂}=0 is present in an actual problem, this diagonal block is removed to ensure that [symbol] ₖ is positive definite, and [symbol] ₖ^{2,j}^{₂}=0 is directly given in an estimation result.

Preferably, an optimal solution for the optimization problem constructed by employing the KL divergence is:

$${\hat{Q}}_{k}^{1 , {j}_{1}} = {\hat{Q}}_{k}^{3 , {j}_{1}} , {λ}_{k}^{{j}_{2}} = \frac{1}{{m}_{{j}_{2}}} tr [ {( {\hat{Q}}_{k}^{c , {j}_{2}} )}^{- 1} {\hat{Q}}_{k}^{4 , {j}_{2}} ] ;$$

where mⱼ_{₂} is the dimension of [symbol] ₖ^{c,j}^{₂}; [symbol] ₖ^{3,j}^{₁} is a corresponding matrix block of [symbol] ₖ^{1,j}^{₁} in [symbol] ₖ⁰; and [symbol] ₖ^{4,j}^{₂} is a corresponding matrix block of [symbol] ₖ^{2,j}^{₂} in [symbol] ₖ⁰.

Preferably, the augmented estimation problem constructed in step 1 employs a system equation as below:

$${x}_{k} = [ \begin{matrix}{f}_{ξ} ( {ξ}_{k - 1} , {u}_{k - 1} ) + {Gd}_{k - 1} \\ {a}_{k - 1} \\ {d}_{k - 1}\end{matrix} ] + {w}_{k - 1} ;$$

$${y}_{k} = {h}_{ξ} ( {ξ}_{k} , {u}_{k} ) + {Ed}_{k} + {v}_{k} ;$$

where xₖ and yₖ are the augmented state vector and the measurement vector at a k th moment, respectively; ξₖ₋₁ and ξₖ are the state vectors of the unmanned surface vessel at a (k−1)th moment and the k th moment, respectively; uₖ₋₁ and uₖ are the input vectors at the (k−1)th moment and the k th moment, respectively; dₖ₋₁ and dₖ are the unknown input vectors at the (k−1)th moment and the k th moment, respectively; aₖ₋₁ is the parameter vector at the (k−1)th moment; f_{ξ} represents nonlinear mapping from the state vector ξₖ₋₁ and the input vector uₖ₋₁ at the (k−1)th moment to the state vector ξₖ at the k th moment, without the consideration of noises and the unknown input vectors; h_{ξ} represents nonlinear mapping from the state vector ξₖ and the input vector uₖ at the k th moment to the measurement vector yₖ, without the consideration of the noises and the unknown input vectors; wₖ₋₁ is zero mean process noises at the (k−1)th moment; Vₖ is zero mean measurement noises at the k th moment; and in a case that a system sampling period is Tₛ, matrices G and E are expressed as:

$$G = {T}_{s} [ \begin{matrix}{0}_{3 \times 3} \\ {I}_{3}\end{matrix} ] , E = [ \begin{matrix}{0}_{6 \times 2} & {0}_{6 \times 1} \\ {I}_{2} & {0}_{2 \times 1}\end{matrix} ] ;$$

I₂ and I₃ are 2×2 and 3×3 identity matrices, respectively.

Preferably, step 2 specifically includes:
step 21: initializing the adaptive robust unscented Kalman filtering, including an estimated value \hat{x}_{0|0} of the augmented state vector and a covariance matrix P_{0|0}^{xx} of an error thereof;
step 22: acquiring the input vector uₖ and the measurement vector yₖ of the unmanned surface vessel system;
step 23: predicating an augmented state vector \hat{x}_{k|k-1} at the k th moment and a covariance matrix P_{k|k-1}^{xx} of a prediction error of the augmented state vector;
step 24: predicating a measurement vector ŷ_{k|k-1} at the k th moment, a covariance matrix P_{k|k-1}^{yy} of a prediction error of the measurement vector, and a cross covariance matrix P_{k|k-1}^{xy};
step 25: constructing an optimization problem employed by robust state estimation, including:
linearizing a measurement equation for the unmanned surface vessel system by employing results of unscented transformation as follows:

$${y}_{k} - {\hat{y}}_{k \vert k - 1} = {H}_{k} [ {x}_{k} - {\hat{x}}_{k \vert k - 1} ] + {r}_{k ;}$$

$${H}_{k} = {( {P}_{k \vert k - 1}^{xy} )}^{T} {( {P}_{k \vert k - 1}^{xx} )}^{- 1} ;$$

where rₖ is noises of the linearized measurement equation, having a statistical property as below:

$$E [ {r}_{k} ] = 0 , {Ψ}_{k} = E [ {r}_{k} {r}_{k}^{T} ] = {P}_{k \vert k - 1}^{yy} - {( {P}_{k \vert k - 1}^{xy} )}^{T} {( {P}_{k \vert k - 1}^{xx} )}^{- 1} {P}_{k \vert k - 1}^{xy} ;$$

the system with the measurement equation linearized being written as:

$$[ \begin{matrix}{\hat{x}}_{k \vert k - 1} \\ {y}_{k} - {\hat{y}}_{k \vert k - 1} + {H}_{k} {\hat{x}}_{k \vert k - 1}\end{matrix} ] = [ \begin{matrix}I \\ {H}_{k}\end{matrix} ] {x}_{k} + {ξ}_{k} ;$$

where I is an identity matrix, and the vector ξₖ has the following properties:

$${ξ}_{k} = [ \begin{matrix}{\hat{x}}_{k \vert k - 1} - {x}_{k} \\ {r}_{k}\end{matrix} ] ;$$

$$E [ {ξ}_{k} {ξ}_{k}^{T} ] = [ \begin{matrix}{P}_{k \vert k - 1}^{xx} & 0 \\ 0 & {Ψ}_{k}\end{matrix} ] = [ \begin{matrix}{{T}_{k}^{P} ( {T}_{k}^{P} )}^{T} & 0 \\ 0 & {T}_{k}^{ψ} {( {T}_{k}^{ψ} )}^{T}\end{matrix} ] = {T}_{k} {T}_{k}^{T} ;$$

where Tₖ^{P}, Tₖ^{ψ}, and Tₖ are Cholesky factors of P_{k|k-1}^{xx}, Ψₖ, and E[ξₖξₖ^{T}, respectively;
further, the following equation being provided:

$${T}_{k}^{- 1} [ \begin{matrix}{\hat{x}}_{k \vert k ‐ 1} \\ {y}_{k} - {\hat{y}}_{k \vert k ‐ 1} + {H}_{k} {\hat{x}}_{k \vert k ‐ 1}\end{matrix} ] = {T}_{k}^{- 1} [ \begin{matrix}I \\ {H}_{k}\end{matrix} ] {x}_{k} + {T}_{k}^{- 1} {ξ}_{k} ;$$

this equation being rewritten as:

$${Y}_{k} = {A}_{k} {x}_{k} + {e}_{k} ;$$

where:

$${Y}_{k} = {T}_{k}^{- 1} [ \begin{matrix}{\hat{x}}_{k \vert k ‐ 1} \\ {y}_{k} - {\hat{y}}_{k \vert k ‐ 1} + {H}_{k} {\hat{x}}_{k \vert k ‐ 1}\end{matrix} ] , {A}_{k} = {T}_{k}^{- 1} [ \begin{matrix}I \\ {H}_{k}\end{matrix} ] , {e}_{k} = {T}_{k}^{- 1} {ξ}_{k} ;$$

combining the maximum cross entropy criterion and the minimum mean square error criterion, the former being used for processing the process noises and the latter being used for processing the measurement noises; establishing and solving the following optimization problem to obtain optimal estimation \hat{x}_{k|k}:

$${\hat{x}}_{k \vert k} = arg {min}_{{x}_{k}} \{ {\sum }_{i = 1}^{n} [ {G}_{σ} ( 0 ) - {G}_{σ} ( {e}_{k}^{i} ) ] + w {\sum }_{i = n + 1}^{n + m} {( {e}_{k}^{i} )}^{2} \} ;$$

where W is a weight coefficient; n is the dimension of the augmented state vector; M is the dimension of yₖ; eₖⁱ is an ith element of eₖ; σ is bandwidth; and Gσ(·) is Gaussian kernel function;
step 26: obtaining optimal estimation of the augmented state vector according to an iteration form of robust unscented Kalman filtering;
step 27: estimating the process noise covariance matrix by employing an adaptive law having covariance matrix constraints; and
step 28: determining whether to terminate the parameter estimation; if not, returning back to step 22.

Preferably, the state vector of the unmanned surface vessel includes a center-of-mass position X, Y and a yaw angle ψ of the unmanned surface vessel under a world coordinate system, and a center-of-mass velocity U,V and a yaw velocity r of the unmanned surface vessel under a body coordinate system; and the parameter vector of the unmanned surface vessel model includes an inertia-related parameter, a damping-related parameter, and a driving force-related parameter.

Based on the same inventive concept, an adaptive robust estimation system for parameters of an unmanned surface vessel provided by the present invention includes:
a problem construction module, configured to construct an augmented state estimation problem considering an external disturbance for the unmanned surface vessel; augmented state vectors including a state vector of the unmanned surface vessel, a parameter vector of an unmanned surface vessel model, and an unknown input vector representing a modeling error of an unmanned surface vessel system and the external disturbance;
and an adaptive robust estimation module, configured to depending on a real-time input vector and a measurement vector of the unmanned surface vessel system, employ an adaptive robust unscented Kalman filtering method having process noise covariance matrix constraints and based on the combination of a maximum cross entropy criterion and a minimum mean square error criterion to obtain model parameters of the unmanned surface vessel; the input vector including a control signal from a shipborne controller, and the measurement vector including data obtained by GPS and IMU measurement; a method for estimating the process noise covariance matrix including: firstly, employing an innovation-based adaptive method to estimate a noise covariance matrix [symbol] ₖ⁰; then, introducing covariance matrix constraints according to a known structure and dividing a process noise covariance matrix [symbol] ₖ to be estimated into a diagonal block without structure constraints and a diagonal block with structure constraints; and finally, employing KL divergence to construct and solve the following optimization problem:

$${\hat{Q}}_{k}^{1 , {j}_{1}} , {λ}_{k}^{{j}_{2}} = {min}_{{\hat{Q}}_{k}^{1 , {j}_{1}} , {λ}_{k}^{{j}_{2}}} {\int }_{- ∞}^{+ ∞} p ( x \vert {\hat{Q}}_{k}^{0} ) log \frac{p ( x \vert {\hat{Q}}_{k}^{0} )}{p ( x \vert {\hat{Q}}_{k} )} dx .$$

Based on the same inventive concept, a computer system provided by the present invention includes a memory, a processor, and a computer program stored in the memory and capable of running on the processor; when the computer program is loaded to the processor, the steps of the adaptive robust estimation method for parameters of an unmanned surface vessel are implemented.

Beneficial effects: The adaptive robust estimation method for parameters of an unmanned surface vessel set forth by the present invention firstly transforms the model parameter estimation problem of the unmanned surface vessel into the augmented state estimation problem, and then, employs an improved adaptive robust Kalman filtering method to estimate the model parameters of the unmanned surface vessel, depending on the real-time input vector and the measurement vector of the system. By employing the improved robust estimation method combining the maximum cross entropy criterion and the minimum mean square error criterion of the present invention, the robustness to ambient outlier noises can be improved. By employing the adaptive law having covariance matrix constraints set forth by the present invention, high-accuracy estimation of the high-dimensional process noise covariance matrix can be implemented. Simulation results indicate that the present invention can implement precise estimation for the parameters of the unmanned surface vessels.

### BRIEF DESCRIPTION OF THE DRAWINGS

FIG. 1 is a general flowchart of a method according to an embodiment of the present invention.

FIG. 2 is a flowchart of an adaptive robust unscented Kalman filtering method according to an embodiment of the present invention.

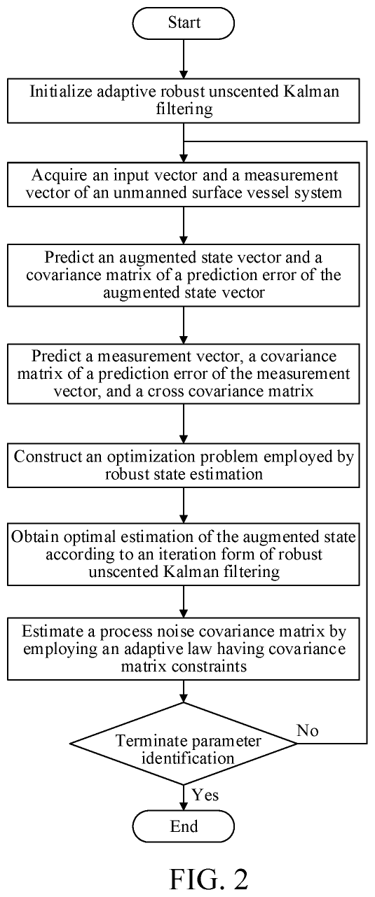

FIG. 3 is an error curve graph of parameters of a twin-propeller differential unmanned surface vessel estimated according to an embodiment of the present invention.

### DETAILED DESCRIPTION

The technical solutions in embodiments of the present invention will be described below clearly and completely with reference to the accompanying drawings in the embodiments of the present invention. Apparently, the described embodiments are merely a part rather than all of the embodiments of the present invention. All other embodiments obtained by a person of ordinary skill in the art based on the embodiments of the present invention without creative efforts shall fall within the protection scope of the present invention.

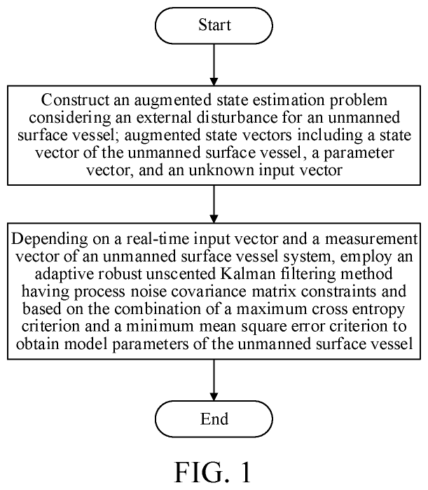

As shown in FIG. 1, an adaptive robust estimation method for parameters of an unmanned surface vessel disclosed by the embodiments of the present invention includes: firstly, an augmented state estimation problem considering an external disturbance for the unmanned surface vessel is constructed, specifically, a system state equation is established according to kinematic and dynamical equations of the unmanned surface vessel, a system measurement equation is established according to real-time kinematic global positioning system and inertial measurement units, an unknown input of a system is introduced, and system parameters and the unknown input are augmented into a state, so as to transform a parameter estimation problem of the unmanned surface vessel into an augmented state estimation problem; then, depending on a real-time input vector and a measurement vector of an unmanned surface vessel system, an adaptive robust unscented Kalman filtering method having process noise covariance matrix constraints and based on the combination of a maximum cross entropy criterion and a minimum mean square error criterion is employed to obtain model parameters of the unmanned surface vessel. Specifically, considering that the state of the unmanned surface vessel system may be disturbed by outlier noises, a robust Kalman filtering method is designed based on the maximum cross entropy criterion and the minimum mean square error criterion; and considering that statistical characteristics of process noises of the unmanned surface vessel system are unknown and the system state dimension is relatively high, an adaptive law having process noise covariance matrix constraints is introduced to precisely estimate the process noise covariance matrix.

The implementation process of the embodiments of the present invention will be described in detail below by taking estimation for model parameters of a twin-propeller differential unmanned surface vessel as an example, which includes the following specific steps:
S1: construction of an augmented state estimation problem considering an external disturbance for the unmanned surface vessel.

When it is assumed that a water flow rate is zero, an unmanned surface vessel model may be expressed with kinematic and dynamical equations, respectively:

$$\dot{η} = R υ ;$$

$$M \dot{υ} + C υ + D υ = τ ;$$

where η=[x, y, ψ]^{T}, X, Y represents a center-of-mass position of the unmanned surface vessel under a world coordinate system and ψ represents a yaw angle of the unmanned surface vessel under the world coordinate system; v=[u, v, r]^{T}, u, v represents a center-of-mass velocity of the unmanned surface vessel under a body coordinate system and r represents a yaw velocity of the unmanned surface vessel under the body coordinate system; R represents a rotation matrix; M is an inertial matrix; C is a Coriolis force matrix; D is a damping matrix; τ is a force borne by the unmanned surface vessel; when ambient disturbances are not considered, τ is composed of a forward thrust τᵤ generated by a driving motor and a torque τᵣ that is, τ=τᵤ, 0, τᵣ]^{T}:
the rotation matrix R, the inertial matrix M, the Coriolis force matrix C, and the damping matrix D are expressed as follows, respectively:

$$R = [ \begin{matrix}cos ψ & - s in ψ & 0 \\ sin ψ & cos ψ & 0 \\ 0 & 0 & 1\end{matrix} ] ; M = [ \begin{matrix}m - {X}_{\dot{u}} & 0 & 0 \\ 0 & m - {Y}_{\dot{v}} & {mx}_{g} - {Y}_{\dot{r}} \\ 0 & {mx}_{g} - {Y}_{\dot{r}} & {I}_{z} - {N}_{\dot{r}}\end{matrix} ] ;$$

$$C = [ \begin{matrix}0 & 0 & - {c}_{31} \\ 0 & 0 & - {c}_{32} \\ {c}_{31} & {c}_{32} & 0\end{matrix} ] ; D = [ \begin{matrix}{d}_{11} & 0 & 0 \\ 0 & {d}_{22} & {d}_{23} \\ 0 & {d}_{32} & {d}_{33}\end{matrix} ] ;$$

where m is a mass of the unmanned surface vessel; I_{z} is a moment of inertia of the unmanned surface vessel; x_{g} is a center-of-mass coordinate; and X_{\dot{u}}, Y_{\dot{v}}, and N_{\dot{r}} are hydrodynamic force derivatives;
c₃₁, c₃₂, d₁₁, d₂₂, d₂₃, d₃₂ and d₃₃ in the Coriolis force matrix C and the damping matrix D are as follows, respectively:

$${c}_{31} = ( m - {Y}_{\dot{v}} ) v + ( {mx}_{g} - {Y}_{\dot{r}} ) r ; {c}_{32} = - ( m - {X}_{\dot{u}} ) u ;$$

$${d}_{11} = - {X}_{u} - {X}_{\vert u \vert u} \vert u \vert ; {d}_{22} = - {Y}_{v} - {Y}_{\vert v \vert v} \vert v \vert ; {d}_{23} = - {Y}_{r} - {Y}_{\vert r \vert r} \vert r \vert ;$$

$${d}_{32} = - {N}_{v} - {N}_{\vert v \vert v} \vert v \vert ; {d}_{33} = - {N}_{r} - {N}_{\vert r \vert r} \vert r \vert ;$$

where Xᵤ, X_{|u|u}, Yᵥ, Y_{|v|v}, Yᵣ, Y_{|r|r}, Nᵥ, N_{|v|v}, Nᵣ and N_{|r|r} are different types of hydrodynamic force derivatives.

With respect to a twin-propeller differential unmanned surface vessel system, a driving force thereof is generated by two (sets of) motors. Under an assumption that rotating speeds of the two (sets of) motors are in direct proportion to control signals τ₁ and τ₂ of a shipborne controller, τᵤ and τᵣ have the following relational expressions with respect to the control signals τ₁ and τ₂:

$${τ}_{u} = {k}_{1} ( \vert {τ}_{1} \vert {τ}_{1} + \vert {τ}_{2} \vert {τ}_{2} ) - {k}_{2} ( \vert {τ}_{1} \vert + \vert {τ}_{2} \vert ) u ;$$

$${τ}_{r} = {k}_{1} l ( \vert {τ}_{1} \vert {τ}_{1} - \vert {τ}_{2} \vert {τ}_{2} ) - {k}_{2} l ( \vert {τ}_{1} \vert - \vert {τ}_{2} \vert ) u ;$$

where k₁ and k₂ are coefficients, and l is a moment arm of a torque generated by each one of the two (sets of) motors. In conjunction with the above expressions, by properly rearranging the kinematic and dynamical equations of the unmanned surface vessel, state equations of the twin-propeller differential unmanned surface vessel system may be obtained:

$$\dot{x} = u cos ψ - v sin ψ ;$$

$$\dot{y} = u sin ψ + v cos ψ ;$$

$$\dot{ψ} = r ;$$

$$\dot{u} = {a}_{1} vr + {a}_{2} {r}^{2} + {a}_{5} u + {a}_{6} \vert u \vert u + {a}_{15} ( \vert {τ}_{1} \vert {τ}_{1} + \vert {τ}_{2} \vert {τ}_{2} ) - {a}_{16} ( \vert {τ}_{1} \vert + \vert {τ}_{2} \vert ) u ;$$

$$\dot{v} = {a}_{3} uv + {a}_{4} ur + {a}_{7} v + {a}_{8} \vert v \vert v + {a}_{9} r + {a}_{10} \vert r \vert r - {a}_{17} ( \vert {τ}_{1} \vert {τ}_{1} - \vert {τ}_{2} \vert {τ}_{2} ) + {a}_{18} ( \vert {τ}_{1} \vert - \vert {τ}_{2} \vert ) u ;$$

$$\dot{r} = \frac{{a}_{1} {a}_{3}}{{a}_{2}} uv - {a}_{3} ur + {a}_{11} v + {a}_{12} \vert v \vert v + {a}_{13} r + {a}_{14} \vert r \vert r + \frac{{a}_{1} {a}_{17}}{{a}_{2}} ( \vert {τ}_{1} \vert {τ}_{1} - \vert {τ}_{2} \vert {τ}_{2} ) - \frac{{a}_{1} {a}_{18}}{{a}_{2}} ( \vert {τ}_{1} \vert - \vert {τ}_{2} \vert ) u ;$$

where a₁, . . . , a₄ are inertia-related parameters, a₅, . . . ,a₁₄ are damping-related parameters, and a₁₅′ . . . a₁₈ are driving force-related parameters. Assuming that a vector a=[a₁, . . . , a₁₈]^{T} represents a parameter vector to be identified, the state vector of the twin-propeller differential unmanned surface vessel is selected as ξ=[x, y, ψ, u, v, r]^{T} and the input vector thereof is selected as u=τ₁,τ₂]^{T} the above equations may be denoted as a discrete state equation below:

$${ξ}_{k} = {f}_{ξ} ( {ξ}_{k - 1} , {u}_{k - 1} ) .$$

It is assumed that the unmanned surface vessel has been equipped with a global positioning system (GPS) and an inertial measurement unit (IMU), the former is used for measuring a position X, Y and a velocity u, v of the unmanned surface vessel and the latter is used for measuring a yaw angle ψ, a yaw velocity r, and an acceleration \dot{u}, \dot{v} of the unmanned surface vessel, then the measurement equation of the system is expressed as below:

$${y}_{k} = {h}_{ξ} ( {ξ}_{k ,} {u}_{k} ) = {[ {x}_{k} , {y}_{k} , {ψ}_{k} , {u}_{k} , {v}_{k} , {r}_{k} , {\dot{u}}_{k} , {\dot{v}}_{k} ]}^{T} .$$

In addition, considering influences caused by unknown inputs such as a modeling error of the unmanned surface vessel system and the external disturbance to dynamics characteristics of the unmanned surface vessel, an unknown input vector dₖ ∈ [symbol] ³ is introduced. To transform the parameter estimation problem of the unmanned surface vessel into the augmented state estimation problem, the following augmented state vector is selected:

$${x}_{k} = {[ \begin{matrix}{ξ}_{k}^{T} & {a}_{k}^{T} & {d}_{k}^{T}\end{matrix} ]}^{T} .$$

In this case, a system equation employed by the augmented state estimation problem may be written as:

$${x}_{k} = f ( {x}_{k - 1} , {u}_{k - 1} ) + {w}_{k - 1} = [ \begin{matrix}{f}_{ξ} ( {ξ}_{k - 1} , {u}_{k - 1} ) + {Gd}_{k - 1} \\ {a}_{k - 1} \\ {d}_{k - 1}\end{matrix} ] + {w}_{k - 1} ;$$

$${y}_{k} = h ( {x}_{k} , {u}_{k} ) + {v}_{k} = {h}_{ξ} ( {ξ}_{k} , {u}_{k} ) + {Ed}_{k} + {v}_{k} ;$$

where f represents nonlinear mapping from an augmented state vector xₖ₋₁ and an input vector uₖ₋₁ at a (k−1)th moment to an augmented state vector xₖ at a k th moment, without the consideration of noises; h represents nonlinear mapping from the augmented state vector xₖ and an input vector Uₖ at the k th moment to a measurement vector yₖ, without the consideration of noises; Wₖ₋₁ and Vₖ are zero mean process noises and zero mean measurement noises of covariance matrices [symbol] ₖ₋₁ and Rₖ at the (k−1)th moment and the k th moment, respectively; and in a case that a system sampling period is Tₛ, matrices G and E are expressed as:

$$G = {T}_{s} [ \begin{matrix}{0}_{3 \times 3} \\ {I}_{3}\end{matrix} ] , E = [ \begin{matrix}{0}_{6 \times 2} & {0}_{6 \times 1} \\ {I}_{2} & {0}_{2 \times 1}\end{matrix} ] ;$$

S2: adaptive robust unscented Kalman filtering having process noise covariance matrix constraints is employed to obtain model parameters of the unmanned surface vessel.

S21: the adaptive robust unscented Kalman filtering is initialized.

An initial augmented state vector estimated value \hat{X}_{0|0} is selected and the value should be approximate to actual initial augmented state vector, parameters and unknown input of the unmanned surface vessel. At the same time, a covariance matrix P_{0|0}^{xx} of an error of the initial augmented state vector estimated value is given.

S22: the input vector and the measurement vector of the unmanned surface vessel system are acquired.

An input vector uₖ of the unmanned surface vessel system may be directly obtained from a controller, whereas a measurement vector yₖ may be obtained from measurement results of the GPS and the IMU.

S23: an augmented state vector and a covariance matrix of a prediction error of the augmented state vector are predicted.

Firstly, a set of σ sample points X_{k-1|k-1}⁽ⁱ⁾ at the (k−1)th moment are generated:

$${Χ}_{k - 1 \vert k - 1}^{( 0 )} = {\hat{x}}_{k - 1 \vert k - 1} ;$$

$${Χ}_{k - 1 \vert k - 1}^{( i )} = {\hat{x}}_{k - 1 \vert k - 1} + {( \sqrt{{cP}_{k - 1 \vert k - 1}^{xx}} )}_{i} , i = 1 , ... , n ;$$

$${Χ}_{k - 1 \vert k - 1}^{( i )} = {\hat{x}}_{k - 1 \vert k - 1} - {( \sqrt{{cP}_{k - 1 \vert k - 1}^{xx}} )}_{i - n} , i = n + 1 , ... , 2 n ;$$

where \hat{x}_{k-1|k-1} is the augmented state vector estimated at the (k−1)th moment; P_{k-1|k-1}^{xx} is a covariance matrix of an error of this augmented state vector estimated value; n is the dimension of the augmented state vector; c is a constant; and (\sqrt{cP_{k-1|k-1}^{xx}})ᵢ represents a vector composed of an i th column of a Cholesky factor of cP_{k-1|k-1}^{xx}. Then, a predicted value X_{k|k-1}⁽ⁱ⁾ of each σ point is mapped by means of the state equation of the unmanned surface vessel system:

$${Χ}_{k \vert k - 1}^{( i )} = f ( {Χ}_{k - 1 \vert k - 1}^{( i )} , {u}_{k - 1} ) ;$$

an augmented state vector \hat{x}_{k|k-1} at the (k)th moment is predicted according to the predicted value X_{k|k-1}⁽ⁱ⁾ of the σ point:

$${\hat{x}}_{k \vert k - 1} = {\sum }_{i = 0}^{2 n} {W}^{( i )} {Χ}_{k \vert k - 1}^{( i )} ;$$

where W is the weight.

Secondly, the covariance matrix P_{k|k-1}^{xx} of the error of the predicted value of the augmented state vector is calculated:

$${P}_{k \vert k - 1}^{xx} = {\sum }_{i = 0}^{2 n} {W}^{( i )} ( {Χ}_{k \vert k - 1}^{( i )} - {\hat{x}}_{k + 1 \vert k} ) {( {Χ}_{k \vert k - 1}^{( i )} - {\hat{x}}_{k + 1 \vert k} )}^{T} + {Q}_{k} .$$

S24: a measurement vector, a covariance matrix of a prediction error of the measurement vector and a cross covariance matrix are predicted:
σ point X_{k|k-1}⁽ⁱ⁾ is regenerated:

$${Χ}_{k \vert k - 1}^{( 0 )} = {\hat{x}}_{k \vert k - 1} ;$$

$${Χ}_{k \vert k - 1}^{( i )} = {\hat{x}}_{k \vert k - 1} + {( \sqrt{{cP}_{k \vert k - 1}^{xx}} )}_{i} , i = 1 , ... , n ;$$

$${Χ}_{k \vert k - 1}^{( i )} = {\hat{x}}_{k \vert k - 1} - {( \sqrt{{cP}_{k \vert k - 1}^{xx}} )}_{i - n} , i = n + 1 , ... , 2 n ;$$

a measurement vector γ_{k|k-1}⁽ⁱ⁾ predicted by each σ point X_{k|k-1}⁽ⁱ⁾ is calculated:

$${γ}_{k \vert k - 1}^{( i )} = h ( {Χ}_{k \vert k - 1}^{( i )} , {u}_{k} ) ;$$

a measurement vector ŷ_{k|k-1} predicted at the k th moment is calculated:

$${\hat{y}}_{k \vert k - 1} = {\sum }_{i = 0}^{2 n} {W}^{( i )} {γ}_{k \vert k - 1}^{( i )} ;$$

a covariance matrix P_{k|k-1}^{yy} of the prediction error of the measurement vector is calculated:

$${P}_{k \vert k - 1}^{yy} = {\sum }_{i = 0}^{2 n} {W}^{( i )} ( {γ}_{k \vert k - 1}^{( i )} - {\hat{y}}_{k \vert k - 1} ) {( {γ}_{k \vert k - 1}^{( i )} - {\hat{y}}_{k \vert k - 1} )}^{T} + {R}_{k} ;$$

an cross covariance matrix P_{k|k-1}^{yy} between \hat{x}_{k|k-1}^{xy} and ŷ_{k|k-1} is calculated:

$${P}_{k \vert k - 1}^{xy} = {\sum }_{i = 0}^{2 n} {W}^{( i )} ( {χ}_{k \vert k - 1}^{( i )} - {\hat{x}}_{k \vert k - 1} ) {( {γ}_{k \vert k - 1}^{( i )} - {\hat{y}}_{k \vert k - 1} )}^{T} .$$

S25: an optimization problem employed by robust state estimation is constructed.

A measurement equation for the unmanned surface vessel system may be linearized by employing results of unscented transformation as follows:

$${y}_{k} - {\hat{y}}_{k \vert k - 1} = {H}_{k} [ {x}_{k} - {\hat{x}}_{k \vert k - 1} ] + {r}_{k} ;$$

$${H}_{k} = {( {P}_{k \vert k - 1}^{xy} )}^{T} {( {P}_{k \vert k - 1}^{xx} )}^{- 1} ;$$

where rₖ is noises of the linearized measurement equation, which have a statistical property as below:

$$E [ {r}_{k} ] = 0 , {Ψ}_{k} = E [ {r}_{k} {r}_{k}^{T} ] = {P}_{k \vert k - 1}^{yy} - {( {P}_{k \vert k - 1}^{xy} )}^{T} {( {P}_{k \vert k - 1}^{xx} )}^{- 1} {P}_{k \vert k - 1}^{xy} .$$

The system with the measurement equation linearized may be written as:

$$[ \begin{matrix}{\hat{x}}_{k \vert k - 1} \\ {y}_{k} - {\hat{y}}_{k \vert k - 1} + {H}_{k} {\hat{x}}_{k \vert k - 1}\end{matrix} ] = [ \begin{matrix}I \\ {H}_{k}\end{matrix} ] {x}_{k} + {ξ}_{k} ;$$

where:

$${ξ}_{k} = [ \begin{matrix}{\tilde{x}}_{k \vert k - 1} \\ {r}_{k}\end{matrix} ] = [ \begin{matrix}{\hat{x}}_{k \vert k - 1} - {x}_{k} \\ {r}_{k}\end{matrix} ] .$$

It may be verified that, the desire Eξₖ] of ξₖ has zero mean, and a covariance matric E[ξₖξₖ^{T}] thereof may be transformed as:

$$E [ {ξ}_{k} {ξ}_{k}^{T} ] = [ \begin{matrix}{P}_{k \vert k - 1}^{xx} & 0 \\ 0 & {Ψ}_{k}\end{matrix} ] = [ \begin{matrix}{{T}_{k}^{P} ( {T}_{k}^{P} )}^{T} & 0 \\ 0 & {T}_{k}^{ψ} {( {T}_{k}^{ψ} )}^{T}\end{matrix} ] = {T}_{k} {T}_{k}^{T} ;$$

where Tₖ^{P}, Tₖ^{ψ}, Tₖ are Cholesky factors of P_{k|k-1}^{xx}, ψₖ, and E[ξₖ ξₖ^{T}], respectively.

Further, the following equation is provided:

$${T}_{k}^{- 1} [ \begin{matrix}{\hat{x}}_{k \vert k - 1} \\ {y}_{k} - {\hat{y}}_{k \vert k - 1} + {H}_{k} {\hat{x}}_{k \vert k - 1}\end{matrix} ] = {T}_{k}^{- 1} [ \begin{matrix}I \\ {H}_{k}\end{matrix} ] {x}_{k} + {T}_{k}^{- 1} {ξ}_{k} ;$$

This equation is rewritten as:

$${Y}_{k} = {A}_{k} {x}_{k} + {e}_{k} ;$$

where:

$${Y}_{k} = {T}_{k}^{- 1} [ \begin{matrix}{\hat{x}}_{k \vert k - 1} \\ {y}_{k} - {\hat{y}}_{k \vert k - 1} + {H}_{k} {\hat{x}}_{k \vert k - 1}\end{matrix} ] , {A}_{k} = {T}_{k}^{- 1} [ \begin{matrix}I \\ {H}_{k}\end{matrix} ] , {e}_{k} = {T}_{k}^{- 1} {ξ}_{k} .$$

In addition, it may be verified that the mean value of a vector eₖ is 0, and a covariance matrix thereof is an identity matrix. The maximum cross entropy criterion with good robustness is introduced as an optimal criterion, and is combined with the minimum mean square error criterion employed by conventional Kalman filtering. The former is used for processing the process noises possibly having outliers and the latter is used for processing the measurement noises, that is, the former is modeled with respect to the state equation and the latter is modeled with respect to the measurement equation. An optimal estimation \hat{x}_{k|k} integrating the robustness and accuracy may be obtained by establishing and solving the following optimization problem:

$${\hat{x}}_{k \vert k} = arg {min}_{{x}_{k}} \{ {\sum }_{i = 1}^{n} [ {G}_{σ} ( 0 ) - {G}_{σ} ( {e}_{k}^{i} ) ] + w {\sum }_{i = n + 1}^{n + m} {( {e}_{k}^{i} )}^{2} \} ;$$

where W is a manually set weight coefficient and is used for balancing two optimal criteria; M is the dimension of the measurement vector yₖ; eₖⁱ is an i th element of eₖ; σ is bandwidth; and G_{σ}(·) is Gaussian kernel function:

$${G}_{σ} ( e ) = exp ( - \frac{{e}^{2}}{2 {σ}^{2}} ) .$$

S26: optimal estimation of the augmented state is obtained according to an iteration form of robust unscented Kalman filtering.

The optimal solution in S25 satisfies a fixed point equation below and needs to be iteratively solved:

$${\hat{x}}_{k \vert k} = {( {A}_{k}^{T} {W}_{k} {A}_{k} )}^{- 1} {A}_{k}^{T} {W}_{k} {Y}_{k} ;$$

where Wₖ=diag (Wₖ^{x},Iₘ), Iₘ is an m-dimensional identity matrix, and:

$${W}_{k}^{x} = \frac{1}{2 w {σ}^{2}} diag [ {G}_{σ} ( {e}_{k}^{1} ) , … , {G}_{σ} ( {e}_{k}^{n} ) ] .$$

A robust unscented Kalman filter iterative equation as below may be obtained by matrix inversion lemma and properly rearranging the optimal solution:

$${\hat{x}}_{k \vert k}^{( t )} = {\hat{x}}_{k \vert k - 1} + {K}_{k}^{( t )} ( {y}_{k} - {\hat{y}}_{k \vert k - 1} ) ;$$

$${K}_{k}^{( t )} = {\overline{P}}_{k \vert k - 1}^{xx , ( t )} {{H}_{k}^{T} ( {H}_{k} {\overline{P}}_{k \vert k - 1}^{xx , ( t )} {H}_{k}^{T} + {\overline{Ψ}}_{k}^{( t )} )}^{- 1} ;$$

$${\overline{P}}_{k \vert k - 1}^{xx , ( t )} - {{T}_{k}^{P} ( {W}_{k}^{x , ( t )} )}^{- 1} {( {T}_{k}^{P} )}^{T} ;$$

$${\overline{Ψ}}_{k}^{( t )} = {Ψ}_{k} ;$$

$${e}_{k}^{( t )} = {Y}_{k} - {A}_{k} {\hat{x}}_{k \vert k}^{( t - 1 )} ;$$

where the superscript (t) represents a t th iteration; \hat{x}_{k|k}⁽⁰⁾=\hat{x}_{k|k-1}; and in a case that the following conditions are satisfied, let \hat{x}_{k|k}=\hat{x}_{k|k}^{(t)} and Kₖ=K^{t}):

$$\frac{‖ {\hat{x}}_{k \vert k}^{( t )} - {\hat{x}}_{k \vert k}^{( t - 1 )} ‖}{‖ {\hat{x}}_{k \vert k}^{( t - 1 )} ‖} \leq ε ;$$

where ε is a threshold. After that, a covariance matrix of a state prediction error is:

$${P}_{k \vert k}^{xx} = ( I - {K}_{k} {H}_{k} ) {{P}_{k \vert k - 1}^{xx} ( I - {K}_{k} {H}_{k} )}^{T} + {K}_{k} {Φ}_{k} {K}_{k}^{T} .$$

S27: the process noise covariance matrix is estimated by employing an adaptive law having covariance matrix constraints.

On the premise of slow change of the noise covariance matrix and in order to ensure the positive definiteness of the noise covariance matrix, the innovation-based adaptive method may be employed to perform primary estimation of the noise covariance matrix:

$${\hat{Q}}_{k}^{0} = \frac{1}{N} {\sum }_{i = {k}_{0}}^{k} ( {\hat{x}}_{i \vert i} - {\hat{x}}_{i \vert i - 1} ) {( {\hat{x}}_{i \vert i} - {\hat{x}}_{i \vert i - 1} )}^{T} , {k}_{0} = k - N + 1 , k \geq N ;$$

where [symbol] ₖ⁰ is a covariance matrix estimated by the innovation-based adaptive method; k₀ represents an initial moment of a sample used for calculating the covariance matrix; N represents the quantity of the sample used; xî_{i|i-1} is a predicted value of the augmented state vector at an i th moment; and \hat{x}_{i|i} is an estimated value of the augmented state vector at the i th moment. An augmentation system for the unmanned surface vessel is a high-dimensional system and contains 27 dimensions of state variables. Since high-dimensional process noise covariance matrices directly calculated by using the above equation have greater errors, introducing covariance matrix constraints according to a known structure on the premise that the structure of the process noise covariance matrix is known may reduce the estimation error of the covariance matrix. It is assumed that the process noise covariance matrix to be estimated is expressed as:

$${\hat{Q}}_{k} = diag [ {\hat{Q}}_{k}^{1 , 1} , … , {\hat{Q}}_{k}^{1 , {n}_{1}} , {\hat{Q}}_{k}^{2 , 1} , … , {\hat{Q}}_{k}^{2 , {n}_{2}} ] ;$$

where [symbol] ₖ^{1,j}^{₁}, j₁=1, . . . ,n₁ represents a diagonal block without structure constraints, which needs to be solved; the number of [symbol] ₖ^{1,j}^{₁} is n₁; [symbol] ₖ^{2,j}^{₂} represents a diagonal block with structure constraints, that is, [symbol] ₖ^{2,j}^{₂}=λₖ^{j}^{₂} [symbol] ₖ^{c,j}^{₂},j₂=1, . . . , n₂, λₖ^{j}^{₂}<0; [symbol] ₖ^{c,j}^{₂} is a known structure; λₖ^{j}^{₂} is a coefficient to be solved; and the number of [symbol] ₖ^{2,j}^{₂} is n₂. In addition, in a case that [symbol] ₖ^{c,j}^{₂}=0 is present in an actual problem, this diagonal block is removed to ensure that [symbol] ₖ is positive definite, and [symbol] ₖ^{2,j}^{₂}=0 is directly given in an estimation result. Based on a starting point that enables [symbol] ₖ⁰ estimated by using an unconstrained method to be the closest to zero mean Gaussian distribution constituted of [symbol] ₖ considering constraints, the following optimization problem is constructed by employing KL divergence.

The following gives the optimization problem employed by the KL divergence-based covariance matrix constraints:

$${\hat{Q}}_{k}^{1 , {j}_{1}} , {λ}_{k}^{{j}_{2}} = {argmin}_{{\hat{Q}}_{k}^{1 , {j}_{1}} , {λ}_{k}^{{j}_{2}}} {\int }_{- ∞}^{+ ∞} p ( x \vert {\hat{Q}}_{k}^{0} ) log \frac{p ( x \vert {\hat{Q}}_{k}^{0} )}{p ( x \vert {\hat{Q}}_{k} )} dx ;$$

where p(x| [symbol] ₖ⁰) and p(x|ₖ) represent probability density functions of a random variable x with the covariance matrix being [symbol] ₖ⁰ and [symbol] ₖ respectively and obeying zero mean Gaussian distribution:

$$\begin{matrix}p ( x \vert {\hat{Q}}_{k}^{0} ) = \frac{1}{{( 2 π )}^{n / 2} {\vert {\hat{Q}}_{k}^{0} \vert}^{1 / 2}} exp ( - \frac{1}{2} {{x}^{T} ( {\hat{Q}}_{k}^{0} )}^{- 1} x ) ; \\ p ( x \vert {\hat{Q}}_{k} ) = \frac{1}{{( 2 π )}^{n / 2} {\vert {\hat{Q}}_{k} \vert}^{1 / 2}} exp ( - \frac{1}{2} {x}^{T} {\hat{Q}}_{k}^{- 1} x ) ;\end{matrix}$$

An optimal solution below may be obtained by solving the above optimization problem:

$${\hat{Q}}_{k}^{1 , {j}_{1}} = {\hat{Q}}_{k}^{3 , {j}_{1}} , {λ}_{k}^{{j}_{2}} = \frac{1}{{m}_{{j}_{2}}} [ {( {\hat{Q}}_{k}^{c , {j}_{2}} )}^{- 1} {\hat{Q}}_{k}^{4 , {j}_{2}} ] ;$$

where mⱼ_{₂} is the dimension of [symbol] ₖ^{c,j}^{₂}; [symbol] ₖ^{3,j}^{₃} is a corresponding matrix block of [symbol] ₖ^{1,j}^{₁} in [symbol] ₖ⁰ and [symbol] ₖ^{4,j}^{₂} is a corresponding matrix block of [symbol] ₖ^{2,j}^{₂} in [symbol] ₖ⁰.

S28: whether to terminate parameter identification is determined; if not, return back to S22.

In this embodiment, MATLAB 2021b is used as a simulation software to compare the adaptive robust estimation method for parameters of an unmanned surface vessel of the present invention with a conventional unscented Kalman filtering method.

The settings of model parameters of a twin-propeller differential unmanned surface vessel used for simulation are shown in Table 1:

TABLE 1
Settings of Model Parameters of a Twin-propeller
Differential Unmanned Surface Vessel

| Parameter | Numerical Value |
|---|---|
| a₁ | 1.3101 |
| a₂ | 0.0424 |
| a₃ | 0.0951 |
| a₄ | −0.7602 |
| a₅ | −0.0280 |
| a₆ | −0.0514 |
| a₇ | −0.3124 |
| a₈ | −0.7753 |
| a₉ | −0.0106 |
| a₁₀ | −0.0945 |
| a₁₁ | −0.2765 |
| a₁₂ | −0.0707 |
| a₁₃ | −0.6842 |
| a₁₄ | −0.2343 |
| a₁₅ | 0.3876 |
| a₁₆ | 1.9380 |
| a₁₇ | 0.0238 |
| a₁₈ | 0.1189 |

Measurement noises used for simulation are zero mean Gaussian noises, with a covariance matrix as:

$${R}_{k} = diag ( 1 , 1 , 0.7615 , 4 , 4 , 76.15 , 100 , 100 ) \times 1 {0}^{- 4} .$$

Noises experienced by the state vector of the unmanned surface vessel are composed of the zero mean Gaussian noises and outliers. A covariance matrix of the zero mean Gaussian noises is:

$${Q}_{k}^{ξ} = diag ( 1 , 1 , 0.7615 , 25 , 25 , 3.046 ) \times 1 {0}^{- 3} .$$

The outliers are generated once every 10 seconds. The outliers also obey the zero mean Gaussian distribution and have a covariance matrix 10 [symbol] ₖ^{ξ}. The covariance of initial process noises of the adaptive robust unscented Kalman filtering and the unscented Kalman filtering is:

$${Q}_{0} = diag ( 1 , 1 , 0.7615 , 25 , 25 , 3.046 , {0}_{1 \times 18} , 10 , 10 , 10 ) \times 1 {0}^{- 4} .$$

The system input is set as:

$${u}_{k} = [ \begin{matrix}0.5 + 0.6 sin 0.01 k \\ 0.5 + 0.6 cos 0.01 k\end{matrix} ] .$$

The unknown input experienced by the system is set as:

$${d}_{k} = [ \begin{matrix}0.5 cos k - 0.1 \\ 0.5 sin 2 k + 0.1 \\ 2 r and - 1\end{matrix} ] ;$$

where rand represents a uniformly distributed random number in a range from 0 to 1.

The process noise covariance matrix to be estimated has the following known structure:

$${\hat{Q}}_{k} = diag [ {\hat{Q}}_{k}^{2 , 1} , {\hat{Q}}_{k}^{2 , 2} , {\hat{Q}}_{k}^{1 , 1} , {\hat{Q}}_{k}^{2 , 3} , {\hat{Q}}_{k}^{1 , 2} ]$$

where [symbol] ₖ^{c,1} is a two-dimensional identity matrix, that is, [symbol] ₖ^{c,1}=I₂; [symbol] ₖ^{c,2} is a one-dimensional identity matrix, that is, [symbol] ₖ^{c,2}=I₁; and [symbol] ₖ^{c,3} is an 18×18-dimensional identity matrix, that is, [symbol] ₖ^{c,3}=0_{18×18}.

Parameter settings of the adaptive robust unscented Kalman filtering method are: σ=12, ε=10⁻⁶, w=3.5×10⁻⁴, and N=200. The sampling period is Δt=0.1. Initial estimations of the augmented state vectors of the two types of unscented Kalman filtering are identical, the initial estimations of the state vector and the unknown input are set as 0, the parameters a₁, . . . , a₄, a₁₅, . . . , a₁₈ are set as 1, and the parameters a₅, . . . , a₁₄ are set as −1. The duration of simulation is 500 seconds, and 20 times of simulation are performed in total.

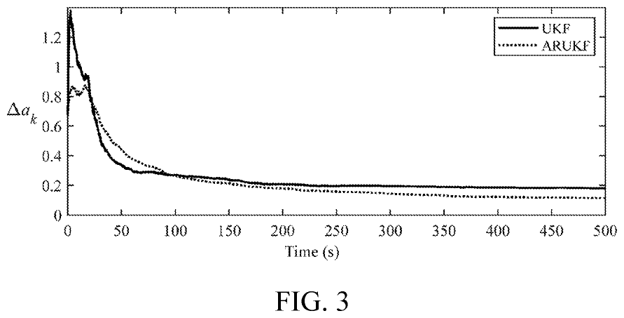

FIG. 3 shows an iteration curve of a parameter error Δaₖ, and Δaₖ is defined as:

$$Δ {a}_{k} = \frac{1}{18} {\sum }_{i = 1}^{18} \sqrt{\frac{1}{20} {\sum }_{t = 1}^{20} {( Δ {a}_{i , k}^{t} )}^{2}} ;$$

where Δa_{i,k}^{t} is an estimation error of an i th parameter at the k th moment in a t th simulation.

In FIG. 3, the solid line marked as UKF represents the error of the parameters estimated by means of the conventional unscented Kalman filtering, and the dotted line marked as ARUKF represents the error of the parameters estimated by means of the adaptive robust unscented Kalman filtering provided by the present invention. It can be seen that, the adaptive robust estimation method for parameters of an unmanned surface vessel of the present invention can implement a better estimation effect.

Based on the same inventive concept, an adaptive robust estimation system for parameters of an unmanned surface vessel provided by the embodiments of the present invention includes: a problem construction module, configured to construct an augmented state estimation problem considering an external disturbance for the unmanned surface vessel; augmented state vectors including a state vector of the unmanned surface vessel, a parameter vector of an unmanned surface vessel model, and an unknown input vector representing a modeling error of an unmanned surface vessel system and the external disturbance; and an adaptive robust estimation module, configured to depending on a real-time input vector and a measurement vector of the unmanned surface vessel system, employ an adaptive robust unscented Kalman filtering method having process noise covariance matrix constraints and based on the combination of a maximum cross entropy criterion and a minimum mean square error criterion to obtain model parameters of the unmanned surface vessel.

For a specific working process of each module described above, reference may be made to a corresponding process in the foregoing method embodiment. Details are not described herein again. The module division is merely logical function division and may be other division in actual implementation. For example, a plurality of modules may be combined or integrated into another system.

Based on the same inventive concept, a computer system disclosed by the embodiments of the present invention includes a memory, a processor, and a computer program stored in the memory and capable of running on the processor; when the computer program is loaded to the processor, the steps of the adaptive robust estimation method for parameters of an unmanned surface vessel are implemented.

A person skilled in the art may understand that, the technical solution of the present invention is essentially or a part contributing to the prior art may be embodied in a form of software products, the computer software product is stored in a storage medium and includes a plurality of instructions for causing a computer system (which may be a personal computer, a server, or a network device) to execute all or some steps of the method according to the embodiments of the present invention. The storage medium includes: various media that can store computer programs, such as a USB flash drive, a removable hard disk, a read-only memory (ROM), a random access memory (RAM), a magnetic disk, or an optical disc.

The above contents are only preferred embodiments of the present invention and are not intended to limit the present invention. Any modification, equivalent replacement, and improvement made within the spirit and principle of the present invention shall be included in the scope of the present invention.

1. An adaptive robust estimation method for parameters of an unmanned surface vessel, comprising the following steps:
step 1: constructing an augmented state estimation problem considering an external disturbance for the unmanned surface vessel; augmented state vectors comprising a state vector of the unmanned surface vessel, a parameter vector of an unmanned surface vessel model, and an unknown input vector representing a modeling error of an unmanned surface vessel system and the external disturbance;
step 2: depending on a real-time input vector and a measurement vector of the unmanned surface vessel system, employing an adaptive robust unscented Kalman filtering method having process noise covariance matrix constraints and based on the combination of a maximum cross entropy criterion and a minimum mean square error criterion to obtain model parameters of the unmanned surface vessel; the input vector comprising a control signal from a shipborne controller, and the measurement vector comprising data obtained by GPS and IMU measurement;
a method for estimating the process noise covariance matrix comprising: firstly, employing an innovation-based adaptive method to estimate a noise covariance matrix [symbol] ₖ⁰; then, introducing covariance matrix constraints according to a known structure and dividing a process noise covariance matrix [symbol] ₖ to be estimated into a diagonal block without structure constraints and a diagonal block with structure constraints; and finally, employing KL divergence to construct and solve the following optimization problem:
$${\hat{Q}}_{k}^{1 , {j}_{1}} , {λ}_{k}^{{j}_{2}} = {min}_{{\hat{Q}}_{k}^{1 , {j}_{1}} , {λ}_{k}^{{j}_{2}}} {\int }_{∞}^{+ ∞} p ( x \vert {\hat{Q}}_{k}^{0} ) log \frac{p ( x \vert {\hat{Q}}_{k}^{0} )}{p ( x \vert {\hat{Q}}_{k} )} dx ;$$
wherein k represents the moment; [symbol] ₖ^{1,j}^{₁} represents the diagonal block without structure constraints; λₖ^{j}^{₂} represents a coefficient of the diagonal block [symbol] ₖ^{2,j}^{₂} with structure constraints; [symbol] ₖ^{2,j}^{₂}=λₖ^{j}^{₂} [symbol] ₖ^{c,j}^{₂}, [symbol] ₖ^{c,j}^{₂} is a known structure; j₁=1, . . . , n₁, j₂=1, . . . , n₂, n₁ and n₂ represent the number of the diagonal block without structure constraints and the number of the diagonal block with structure constraints, respectively; p(x| [symbol] ₖ⁰) and p(x| [symbol] ₖ) represent probability density functions of a random variable X with the covariance matrix being [symbol] ₖ⁰ and [symbol] ₖ respectively and obeying zero mean Gaussian distribution.

2. The adaptive robust estimation method for parameters of an unmanned surface vessel according to claim 1, wherein the noise covariance matrix estimated by the innovation-based adaptive method is expressed as:
$${\hat{Q}}_{k}^{0} = \frac{1}{N} {\sum }_{i = {k}_{0}}^{k} ( {\hat{x}}_{i \vert i} - {\hat{x}}_{i \vert i - 1} ) {( {\hat{x}}_{i \vert i} - {\hat{x}}_{i \vert i - 1} )}^{T} , {k}_{0} = k - N + 1 , k \geq N$$
wherein k₀ represents an initial moment of a sample used for calculating the covariance matrix; N represents the quantity of the sample used; and \hat{x}_{i|i-1} and x_{i|i} are a predicted value and an estimated value of the augmented state vector at an i th moment, respectively.

3. The adaptive robust estimation method for parameters of an unmanned surface vessel according to claim 1, wherein the process noise covariance matrix to be estimated is expressed as:
$${\hat{Q}}_{k} = diag [ {\hat{Q}}_{k}^{1 , 1} , … , {\hat{Q}}_{k}^{1 , {n}_{1}} , {\hat{Q}}_{k}^{2 , 1} , … , {\hat{Q}}_{k}^{2 , {n}_{2}} ] ;$$
in a case that [symbol] ^{c,j}^{₂}=0 is present in an actual problem, this diagonal block is removed to ensure that [symbol] ₖ is positive definite, and [symbol] ^{2,j}^{₂}=0 is directly given in an estimation result.

4. The adaptive robust estimation method for parameters of an unmanned surface vessel according to claim 1, wherein an optimal solution for the optimization problem constructed by employing the KL divergence is:
$${\hat{Q}}_{k}^{1 , {j}_{1}} = {\hat{Q}}_{k}^{3 , {j}_{1}} , {λ}_{k}^{{j}_{2}} = \frac{1}{{m}_{{j}_{2}}} tr [ {( {\hat{Q}}_{k}^{c , {j}_{2}} )}^{- 1} {\hat{Q}}_{k}^{4 , {j}_{2}} ] ;$$
wherein mⱼ₂ is the dimension of [symbol] ₖ^{c,j}^{₂}; Qₖ^{3,j}^{₁} is a corresponding matrix block of [symbol] ₖ^{1,j}^{ᵢ} in [symbol] ₖ⁰ and [symbol] ₖ^{4,j}^{₂} is a corresponding matrix block of [symbol] ₖ^{2,j}^{₂} in [symbol] ₖ⁰.

5. The adaptive robust estimation method for parameters of an unmanned surface vessel according to claim 1, wherein the augmented estimation problem constructed in step 1 employs a system equation as below:
$${x}_{k} = [ \begin{matrix}{f}_{ξ} ( {ξ}_{k ‐ 1} , {u}_{k - 1} ) + G {d}_{k - 1} \\ {a}_{k - 1} \\ {d}_{k - 1}\end{matrix} ] + {w}_{k - 1} ;$$
$${y}_{k} = {h}_{ξ} ( {ξ}_{k} , {u}_{k} ) + E {d}_{k} + {v}_{k} ;$$
wherein Xₖ and yₖ are the augmented state vector and the measurement vector at a k th moment, respectively; ξₖ₋₁ and ξₖ are the state vectors of the unmanned surface vessel at a (k−1)th moment and the k th moment, respectively; uₖ₋₁ and uₖ are the input vectors at the (k−1)th moment and the k th moment, respectively; dₖ₋₁ and dₖ are the unknown input vectors at the (k−1)th moment and the k th moment, respectively; aₖ₋₁ is the parameter vector at the (k−1)th moment; f_{ξ} represents nonlinear mapping from the state vector ξₖ₋₁ and the input vector uₖ₋₁ at the (k−1)th moment to the state vector ξₖ at the k th moment, without the consideration of noises and the unknown input vectors h_{ξ} represents nonlinear mapping from the state vector ξₖ and the input vector uₖ at the k th moment to the measurement vector yₖ, without the consideration of the noises and the unknown input vectors; wₖ₋₁ is zero mean process noises at the (k−1)th moment; Vₖ is zero mean measurement noises at the k th moment; and in a case that a system sampling period is Tₛ, matrices G and E are expressed as:
$$G = {T}_{s} [ \begin{matrix}{0}_{3 \times 3} \\ {I}_{3}\end{matrix} ] , E = [ \begin{matrix}{0}_{6 \times 2} & {0}_{6 \times 1} \\ {I}_{2} & {0}_{2 \times 1}\end{matrix} ] ;$$
I₂ and I₃ are 2×2 and 3×3 identity matrices, respectively.

6. The adaptive robust estimation method for parameters of an unmanned surface vessel according to claim 5, wherein step 2 specifically comprises:
step 21: initializing the adaptive robust unscented Kalman filtering, comprising an estimated value \hat{x}_{0|0} of the augmented state vector and a covariance matrix P_{0|0}^{xx} of an error thereof;
step 22: acquiring the input vector uₖ and the measurement vector yₖ of the unmanned surface vessel system;
step 23: predicating an augmented state vector \hat{x}_{k|k-1} at the k th moment and a covariance matrix P_{k|k-1}^{xx} of a prediction error of the augmented state vector;
step 24: predicating a measurement vector ŷ_{k|k-1} at the k th moment, a covariance matrix P_{k|k-1}^{yy} of a prediction error of the measurement vector, and a cross covariance matrix P_{k|k-1}^{yy};
step 25: constructing an optimization problem employed by robust state estimation, comprising:
linearizing a measurement equation for the unmanned surface vessel system by employing results of unscented transformation as follows:
$${y}_{k} - {\hat{y}}_{k \vert k - 1} = {H}_{k} [ {x}_{k} - {\hat{x}}_{k \vert k - 1} ] + {r}_{k} ;$$
$${H}_{k} = {( {P}_{k \vert k - 1}^{x y} )}^{T} {( {P}_{k \vert k - 1}^{x x} )}^{- 1} ;$$
wherein rₖ is noises of the linearized measurement equation, having a statistical property as below:
$$E [ {r}_{k} ] = 0 , {Ψ}_{k} = E [ {r}_{k} {r}_{k}^{T} ] = {P}_{k \vert k - 1}^{yy} - {( {P}_{k \vert k - 1}^{x y} )}^{T} {( {P}_{k \vert k - 1}^{x x} )}^{- 1} {P}_{k \vert k - 1}^{x y} ;$$
the system with the measurement equation linearized being written as:
$$[ \begin{matrix}{\hat{x}}_{k \vert k - 1} \\ {y}_{k} - {\hat{y}}_{k \vert k - 1} + {H}_{k} {\hat{x}}_{k \vert k - 1}\end{matrix} ] = [ \begin{matrix}I \\ {H}_{k}\end{matrix} ] {x}_{k} + {ξ}_{k} ;$$
wherein I is an identity matrix, and the vector ξₖ has the following properties:
$${ξ}_{k} = [ \begin{matrix}{\hat{x}}_{k \vert k - 1} - {x}_{k} \\ {r}_{k}\end{matrix} ] ;$$
$$E [ {ξ}_{k} {ξ}_{k}^{T} ] = [ \begin{matrix}{P}_{k \vert k - 1}^{xx} & 0 \\ 0 & {Ψ}_{k}\end{matrix} ] = [ \begin{matrix}{{T}_{k}^{P} ( {T}_{k}^{P} )}^{T} & 0 \\ 0 & {{T}_{k}^{ψ} ( {T}_{k}^{ψ} )}^{T}\end{matrix} ] = {T}_{k} {T}_{k}^{T} ;$$
wherein Tₖ^{P}, Tₖ^{ψ}, and Tₖ are Cholesky factors of P_{k|k-1}^{xx}, ψₖ, and E[ξₖξₖ^{T}], respectively;
further, the following equation being provided:
$${T}_{k}^{- 1} [ \begin{matrix}{\hat{x}}_{k \vert k - 1} \\ {y}_{k} - {\hat{y}}_{k \vert k - 1} + {H}_{k} {\hat{x}}_{k \vert k - 1}\end{matrix} ] = {T}_{k}^{- 1} [ \begin{matrix}I \\ {H}_{k}\end{matrix} ] {x}_{k} + {T}_{k}^{- 1} {ξ}_{k} ;$$
this equation being rewritten as:
$${Y}_{k} = {A}_{k} {x}_{k} + {e}_{k} ;$$
wherein:
$${Y}_{k} = {T}_{k}^{- 1} [ \begin{matrix}{\hat{x}}_{k \vert k - 1} \\ {y}_{k} - {\hat{y}}_{k \vert k - 1} + {H}_{k} {\hat{x}}_{k \vert k - 1}\end{matrix} ] , {A}_{k} = {T}_{k}^{- 1} [ \begin{matrix}I \\ {H}_{k}\end{matrix} ] , {e}_{k} = {T}_{k}^{- 1} {ξ}_{k} ;$$
combining the maximum cross entropy criterion and the minimum mean square error criterion, the former being used for processing the process noises and the latter being used for processing the measurement noises; establishing and solving the following optimization problem to obtain optimal estimation \hat{x}_{k|k}:
$${\hat{x}}_{k \vert k} = arg {min}_{{x}_{k}} \{ {\sum }_{i = 1}^{n} [ {G}_{σ} ( 0 ) - {G}_{σ} ( {e}_{k}^{i} ) ] + w {\sum }_{i = n + 1}^{n + m} ( {e}_{k}^{i} ) \} ;$$
wherein W is a weight coefficient; n is the dimension of the augmented state vector; m is the dimension of yₖ; eₖⁱ is an i th element of eₖ; σ is bandwidth; and G_{σ}(·) is Gaussian kernel function;
step 26: obtaining optimal estimation of the augmented state vector according to an iteration form of robust unscented Kalman filtering;
step 27: estimating the process noise covariance matrix by employing an adaptive law having covariance matrix constraints; and
step 28: determining whether to terminate the parameter estimation; if not, returning back to step 22.

7. The adaptive robust estimation method for parameters of an unmanned surface vessel according to claim 1, wherein the state vector of the unmanned surface vessel comprises a center-of-mass position x, y and a yaw angle ψ of the unmanned surface vessel under a world coordinate system, and a center-of-mass velocity u, v and a yaw velocity r of the unmanned surface vessel under a body coordinate system; and the parameter vector of the unmanned surface vessel model comprises an inertia-related parameter, a damping-related parameter, and a driving force-related parameter.

8. The adaptive robust estimation method for parameters of an unmanned surface vessel according to claim 7, wherein in conjunction with kinematic and dynamical equations, state equations of a twin-propeller differential unmanned surface vessel system are obtained:
$$\dot{x} = u cos ψ - v sin ψ ;$$
$$\dot{y} = u sin ψ + v cos ψ ;$$
$$\dot{ψ} = r ;$$
$$\dot{u} = {a}_{1} v r + {a}_{2} {r}^{2} + {a}_{5} u + {a}_{6} \vert u \vert u + {a}_{15} ( \vert {τ}_{1} \vert {τ}_{1} + \vert {τ}_{2} \vert {τ}_{2} ) - {a}_{16} ( \vert {τ}_{1} \vert + \vert {τ}_{2} \vert ) u ;$$
$$\dot{v} = {a}_{3} u v + {a}_{4} u r + {a}_{7} v + {a}_{8} \vert v \vert v + {a}_{9} r + {a}_{10} \vert r \vert r - {a}_{17} ( \vert {τ}_{1} \vert {τ}_{1} - \vert {τ}_{2} \vert {τ}_{2} ) + {a}_{18} ( \vert {τ}_{1} \vert - \vert {τ}_{2} \vert ) u ;$$
$$\dot{r} = - \frac{{a}_{1} {a}_{3}}{{a}_{2}} u v - {a}_{3} u r + {a}_{11} v + {a}_{12} \vert v \vert v + {a}_{13} r + {a}_{14} \vert r \vert r + \frac{{a}_{1} {a}_{17}}{{a}_{2}} ( \vert {τ}_{1} \vert {τ}_{1} - \vert {τ}_{2} \vert {τ}_{2} ) - \frac{{a}_{1} {a}_{18}}{{a}_{2}} ( \vert {τ}_{1} \vert - \vert {τ}_{2} \vert ) u ;$$
wherein a₁, . . . , a₄ are the inertia-related parameters, a₅, . . . , a₁₄ are the damping-related parameters, a₁₅, . . . , a₁₈ are the driving force-related parameters, and τ₁ and τ₂ are control signals used for controlling rotating speeds of two (sets of) motors.

9. An adaptive robust estimation system for parameters of an unmanned surface vessel, comprising:
a problem construction module, configured to construct an augmented state estimation problem considering an external disturbance for the unmanned surface vessel; augmented state vectors comprising a state vector of the unmanned surface vessel, a parameter vector of an unmanned surface vessel model, and an unknown input vector representing a modeling error of an unmanned surface vessel system and the external disturbance;
and an adaptive robust estimation module, configured to depending on a real-time input vector and a measurement vector of the unmanned surface vessel system, employ an adaptive robust unscented Kalman filtering method having process noise covariance matrix constraints and based on the combination of a maximum cross entropy criterion and a minimum mean square error criterion to obtain model parameters of the unmanned surface vessel; the input vector comprising a control signal from a shipborne controller, and the measurement vector comprising data obtained by GPS and IMU measurement; a method for estimating the process noise covariance matrix comprising: firstly, employing an innovation-based adaptive method to estimate a noise covariance matrix [symbol] ₖ⁰; then, introducing covariance matrix constraints according to a known structure and dividing a process noise covariance matrix [symbol] ₖ to be estimated into a diagonal block without structure constraints and a diagonal block with structure constraints; and finally, employing KL divergence to construct and solve the following optimization problem:
$${\hat{Q}}_{k}^{1 , {j}_{1}} , {λ}_{k}^{{j}_{2}} = {min}_{{Q}_{k}^{1 , {j}_{2}} , {λ}_{k}^{{j}_{2}}} {\int }_{- ∞}^{+ ∞} p ( x \vert {\hat{Q}}_{k}^{0} ) log \frac{p ( x \vert {\hat{Q}}_{k}^{0} )}{p ( x \vert {\hat{Q}}_{k} )} dx ;$$
wherein k represents the moment; [symbol] ₖ^{1,j}^{₁} represents the diagonal block without structure constraints; λₖ^{j}^{₂} represents a coefficient of the diagonal block [symbol] ₖ^{2,j}^{₂} with structure constraints; [symbol] ₖ^{2,j}^{₂}=λₖ^{j}^{₂} [symbol] ₖ^{c,j2}, [symbol] ₖ^{c,j}^{₂} is a known structure; j₁=, . . . , n₁, j₂=1, . . . , n₂ n₁ and n₂ represent the number of the diagonal block without structure constraints and the number of the diagonal block with structure constraints, respectively; p(x| [symbol] ₖ⁰) and p(x| [symbol] ₖ) represent probability density functions of a random variable X with the covariance matrix being [symbol] ₖ⁰ and [symbol] ₖrespectively and obeying zero mean Gaussian distribution.

10. A computer system, comprising a memory, a processor, and a computer program stored in the memory and capable of running on the processor, wherein when the computer program is loaded to the processor, the steps of the adaptive robust estimation method for parameters of an unmanned surface vessel according to claim 1 are implemented.
